(19) United States
(12) Patent Application Publication
(10) Pub. No.: US 2026/0119730 A1
(43) Pub. Date: Apr. 30, 2026

(54) NON-TRANSITORY COMPUTER-READABLE RECORDING MEDIUM, LAYOUT GENERATION DEVICE, AND LAYOUT GENERATION METHOD

(71) Applicant: Fujitsu Limited, Kawasaki-shi (JP)

(72) Inventors: Shuang CHANG, Yokohama (JP); Shohei YAMANE, Kawasaki (JP)

(73) Assignee: Fujitsu Limited, Kawasaki-shi (JP)

(21) Appl. No.: 19/367,223

(22) Filed: Oct. 23, 2025

(30) Foreign Application Priority Data
Oct. 28, 2024 (JP) 2024-188749

(51) Int. Cl. G06F 30/13; G06Q 30/0201

(52) U.S. Cl. CPC G06F 30/13; G06Q 30/020112

(57) ABSTRACT

A non-transitory computer-readable recording medium stores therein a layout generation program that causes a computer to execute a process including performing a first causal search for a plurality of products and an evaluation value of a product layout based on a result of a simulation of a customer behavior executed using each of a plurality of the product layouts in a store and obtaining a causal relationship between the plurality of products and the evaluation value, specifying a product arrangement pattern that affects the evaluation value based on the causal relationship, performing a second causal search for the plurality of products, the evaluation value, and the product arrangement pattern, generating a specific product layout based on a result of the second causal search, and outputting the specific product layout.

### CROSS-REFERENCE TO RELATED APPLICATION

This application is based upon and claims the benefit of priority of the prior Japanese Patent Application No. 2024-188749, filed on Oct. 28, 2024, the entire contents of which are incorporated herein by reference.

### FIELD

The embodiments discussed herein are related to a layout generation technique.

### BACKGROUND

Regarding optimization of a product layout in a store, a system for tracking a shopper and an interaction with a product in a store without a cash register is known (see, for example, U.S. Patent Application Publication No. 2020/0118401).

### SUMMARY

According to an aspect of an embodiment, a non-transitory computer-readable recording medium stores therein a layout generation program that causes a computer to execute a process including performing a first causal search for a plurality of products and an evaluation value of a product layout based on a result of a simulation of a customer behavior executed using each of a plurality of the product layouts in a store and obtaining a causal relationship between the plurality of products and the evaluation value, specifying a product arrangement pattern that affects the evaluation value based on the causal relationship, performing a second causal search for the plurality of products, the evaluation value, and the product arrangement pattern, generating a specific product layout based on a result of the second causal search, and outputting the specific product layout.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a functional configuration diagram of a layout generation device according to an embodiment;

FIG. 2 is a flowchart of a first layout generation process;

FIG. 3 is a functional configuration diagram illustrating a specific example of the layout generation device;

FIG. 4 is a diagram illustrating a floor map of a store;

FIG. 5 is a diagram illustrating a product layout in the store;

FIG. 6 is a diagram illustrating customer behavior information;

FIG. 7 is a diagram illustrating integrated behavior information;

FIG. 8 is a diagram illustrating a first causal graph;

FIG. 9 is a diagram illustrating a sorting result of categories;

FIG. 10 is a diagram illustrating the integrated behavior information to which items are added;

FIG. 11 is a diagram illustrating a product position in the product layout;

FIG. 12 is a diagram illustrating a first causal graph including a causal relationship between two products;

FIG. 13 is a diagram illustrating a first causal graph including a causal relationship between an entrance and a circulation distance;

FIG. 14 is a diagram illustrating a causal relationship included in a second causal graph;

FIGS. 15A to 15C are diagrams illustrating an optimized product layout;

FIG. 16 is a flowchart of a second layout generation process; and

FIG. 17 is a hardware configuration diagram of an information processing apparatus.

### DESCRIPTION OF EMBODIMENTS

It is difficult to determine an effective product layout based on empirical knowledge about product sales in a store.

Preferred embodiments of the present invention will be explained with reference to accompanying drawings.

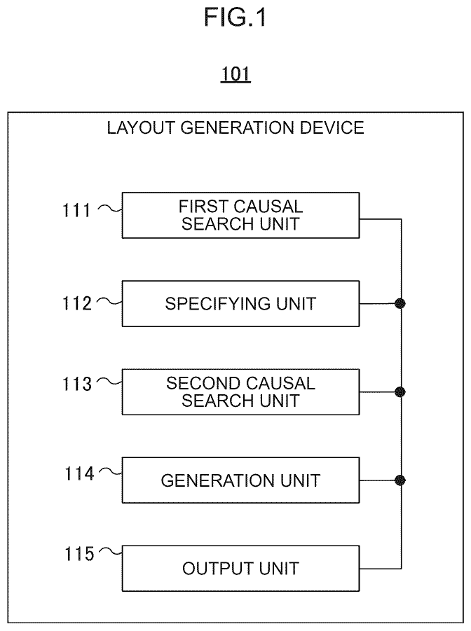

FIG. 1 illustrates a functional configuration example of a layout generation device according to an embodiment. A layout generation device 101 in FIG. 1 includes a first causal search unit 111, a specifying unit 112, a second causal search unit 113, a generation unit 114, and an output unit 115.

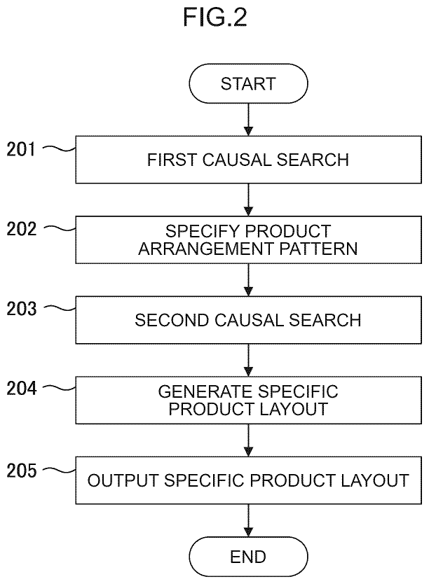

FIG. 2 is a flowchart illustrating an example of a first layout generation process performed by the layout generation device 101 in FIG. 1. First, the first causal search unit 111 performs a first causal search for a plurality of products and an evaluation value of the product layout and obtains a causal relationship between the plurality of products and the evaluation value (step 201). The first causal search unit 111 performs the first causal search based on a result of a simulation of a customer behavior executed using each of the plurality of product layouts in the store.

Next, the specifying unit 112 specifies a product arrangement pattern that affects the evaluation value based on the causal relationship (step 202).

Next, the second causal search unit 113 performs a second causal search for the plurality of products, the evaluation value, and the product arrangement pattern (step 203), and the generation unit 114 generates a specific product layout based on a result of the second causal search (step 204). Then, the output unit 115 outputs a specific product layout (step 205).

According to the layout generation device 101 of FIG. 1, it is possible to present an appropriate product layout in a store.

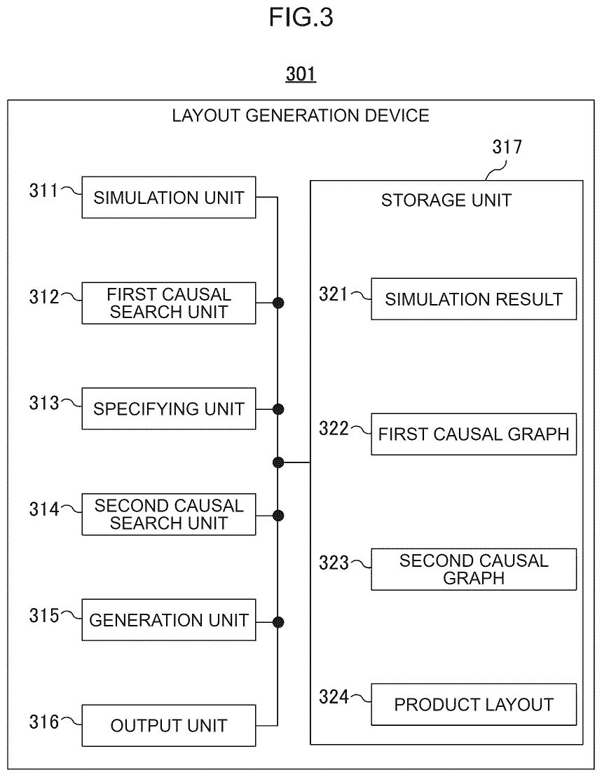

FIG. 3 illustrates a specific example of the layout generation device 101 of FIG. 1. A layout generation device 301 of FIG. 3 includes a simulation unit 311, a first causal search unit 312, a specifying unit 313, a second causal search unit 314, a generation unit 315, an output unit 316, and a storage unit 317. The layout generation device 301 performs a layout generation process of optimizing a product layout in a store.

The first causal search unit 312, the specifying unit 313, the second causal search unit 314, the generation unit 315, and the output unit 316 correspond to the first causal search unit 111, the specifying unit 112, the second causal search unit 113, the generation unit 114, and the output unit 115 in FIG. 1, respectively.

The simulation unit 311 randomly generates N (N is an integer of 2 or more) product layouts for a plurality of products to be sold in the store. Then, the simulation unit 311 executes a simulation of a customer behavior using each product layout, generates a simulation result 321 including individual behavior information and integrated behavior information, and stores the simulation result in the storage unit 317.

The individual behavior information includes N pieces of customer behavior information. The pieces of customer behavior information represent customer behaviors of M customers (M is an integer of 2 or more) with respect to one of the N product layouts. The integrated behavior information is information obtained by integrating N pieces of customer behavior information.

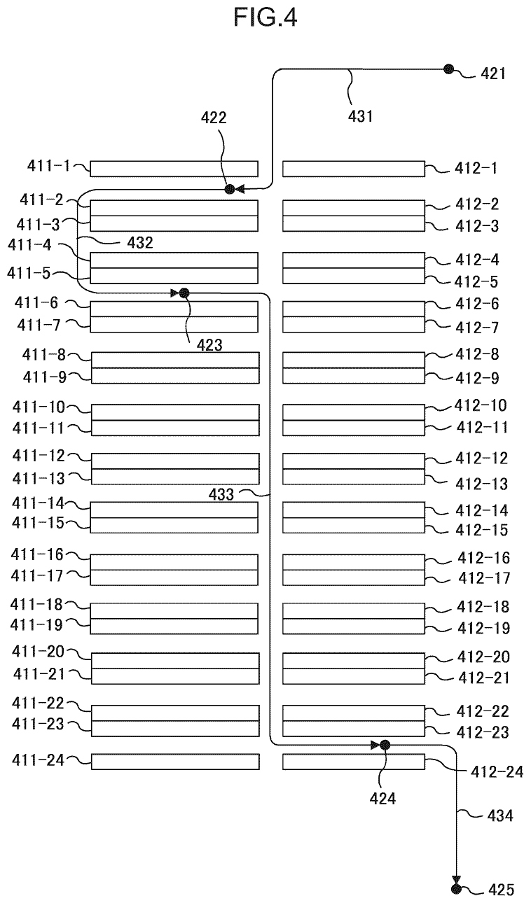

FIG. 4 illustrates an example of a floor map of the store. The store in FIG. 4 is, for example, a supermarket, and products are displayed in product racks 411-1 to 411-24 and product racks 412-1 to 412-24.

In the simulation of the customer behavior, the customer who enters the store for shopping moves, for example, along the movement route indicated by arrows 431 to 434 and stops at stop positions 421 to 425. Therefore, on the arrow between two consecutive stop positions on the movement route, the customer is walking without stopping.

In this case, it is estimated that an action for the product displayed on the product rack 411-1 or the product rack 411-2 occurs at the stop position 422. An action for a product represents that the customer is looking at or taking the product. It is estimated that an action for the product displayed on the product rack 411-5 or the product rack 411-6 occurs at the stop position 423. It is estimated that an action for the product displayed on the product rack 412-23 or the product rack 412-24 occurs at the stop position 424.

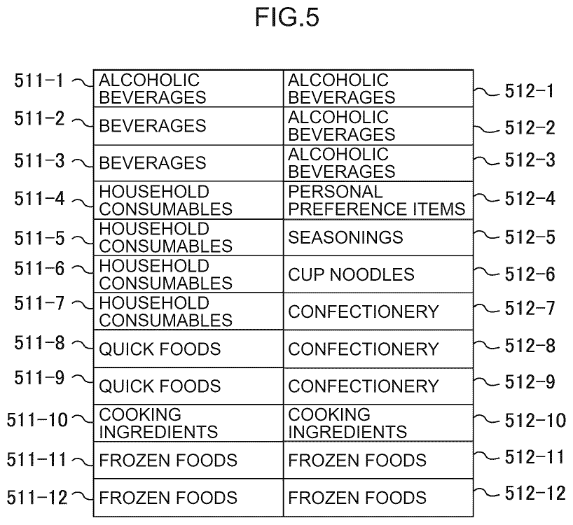

FIG. 5 illustrates an example of a product layout in the store of FIG. 4. A product area 511-i (i=1 to 12) corresponds to a product rack 411-(2i−1) and a product rack 411-2i. The product rack 411-(2i−1) and the product rack 411-2i face each other across the passage. A product area 512-i (i=1 to 12) corresponds to a product rack 412-(2i−1) and a product rack 412-2i. The product rack 412-(2i−1) and the product rack 412-2i face each other across the passage.

The categories of the products arranged in the product area 511-1 and the product areas 512-1 to 512-3 are alcoholic beverages. The categories of the products arranged in the product areas 511-2 and 511-3 are beverages. The categories of products arranged in the product areas 511-4 to 511-7 are household consumables. The household consumables represent consumables such as shampoos and detergents.

The categories of the products arranged in the product areas 511-8 and 511-9 are quick foods. The quick foods represent food that is simple to cook, such as retort food. The categories of the products arranged in the product areas 511-10 and 512-10 are cooking ingredients. The categories of the products arranged in the product areas 511-11, 511-12, 512-11, and 512-12 are frozen foods.

The category of the product arranged in the product area 512-4 is a personal preference item. The category of the product arranged in the product area 512-5 is seasonings. The category of the product arranged in the product area 512-6 is cup noodles. The categories of the products arranged in the product areas 512-7 to 512-9 are confectionery.

In the simulation of the customer behavior, the simulation unit 311 generates N product layouts by randomly changing the categories of the products arranged in each product area.

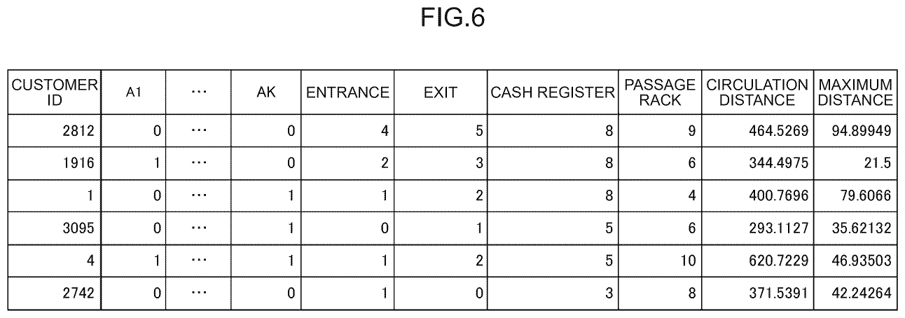

FIG. 6 illustrates an example of the customer behavior information included in the individual behavior information. The customer action information in FIG. 6 represents customer behaviors of the M customers with respect to one of the N product layouts and includes a customer ID, actions A1 to AK (K is an integer of 2 or more), an entrance, an exit, a cash register, a passage rack, a circulation distance, and a maximum distance. In this example, M=6.

The customer ID is identification information of the customer. The action Aj (j=1 to K) indicates whether the customer stops in the product area in which the product of the category Cj is arranged among categories C1 to CK of the products included in the product layout. Aj=1 indicates that the customer has stopped, and Aj=0 indicates that the customer has not stopped. Therefore, when Aj=1, it is estimated that an action for the product of the category Cj has occurred.

The occurrence of an action for a product indicates that the customer is interested in the product. Therefore, by acquiring the action Aj by simulation of the customer behavior, it is possible to collect the information on the preference of each customer for the product of each category Cj.

For example, in the case of the product layout of FIG. 5, K=10, and the category Cj is any one of alcoholic beverages, beverages, household consumables, quick foods, cooking ingredients, frozen foods, personal preference items, seasonings, cup noodles, and confectionery.

The entrance is identification information of an entrance where the customer has entered, and the exit is identification information of an exit where the customer has left the store. The cash register is identification information of a cash register used for settlement of a product purchased by a customer. The passage rack represents the number of product racks that customers have passed on the movement route.

The circulation distance represents a movement distance in which a customer moves from entering the store to leaving the store, and the maximum distance represents the longest distance among distances between two consecutive stop positions on the movement route. In the example of FIG. 4, the sum of the distances indicated by arrows 431 to 434 corresponds to the circulation distance, and the distance indicated by the arrow 433 corresponds to the maximum distance. Since comfort felt by the customer during shopping decreases as the maximum distance increases, the maximum distance represents the degree of comfort of the customer.

By acquiring the circulation distance by simulation of the customer behavior, it is possible to evaluate the product layout based on the movement distance of each customer. Also, by acquiring the maximum distance by simulation of the customer behavior, it is possible to evaluate the product layout based on the comfort of each customer. The circulation distance and the maximum distance are examples of evaluation values of the product layout.

For example, the customer “1916” enters the store from the entrance “2”, stops in the product area where the product of the category C1 is arranged, and does not stop in the product area where the product of category CK is arranged. The customer “1916” passes in front of six product racks, makes settlement at the cash register “8”, and leaves the store from the exit “3”. The customer “1916” has a circulation distance of 344.4975 and a maximum distance of 21.5.

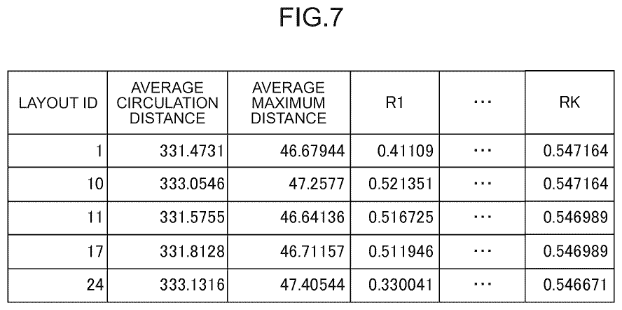

FIG. 7 illustrates an example of the integrated behavior information. The integrated behavior information in FIG. 7 is information obtained by integrating N pieces of the customer behavior information and includes a layout ID, an average circulation distance, an average maximum distance, and action occurrence rates R1 to RK. In this example, N=5.

The layout ID is identification information of a product layout. The average circulation distance represents an average value of circulation distances of the M customers with respect to the product layout indicated by the layout ID. The average maximum distance represents an average value of maximum distances of the M customers with respect to the product layout indicated by the layout ID.

The action occurrence rate Rj (j=1 to K) represents a rate of customers who have stopped in the product area in which the products of the category Cj are arranged among the M customers. Since it is estimated that as the action occurrence rate Rj is larger, popularity for the product of the category Cj is higher, the action occurrence rate Rj represents a customer popularity for the product of the category Cj.

For example, the average circulation distance of the product layout “1” is 331.4731, and the average maximum distance is 46.67944. The action occurrence rate R1 for the product of the category C1 is 0.41109, and the action occurrence rate RK for the product of the category CK is 0.547164. Therefore, the product of the category CK in the product layout “1” is more popular than the product of the category C1.

The first causal search unit 312 performs the first causal search using the simulation result 321 to generate a first causal graph 322 representing the causal relationship between each category of the product and the circulation distance and the maximum distance and stores the first causal graph in the storage unit 317. The causal graph includes a plurality of nodes representing a cause or a result in the causal relationship and an edge from the node representing the cause to the node representing the result.

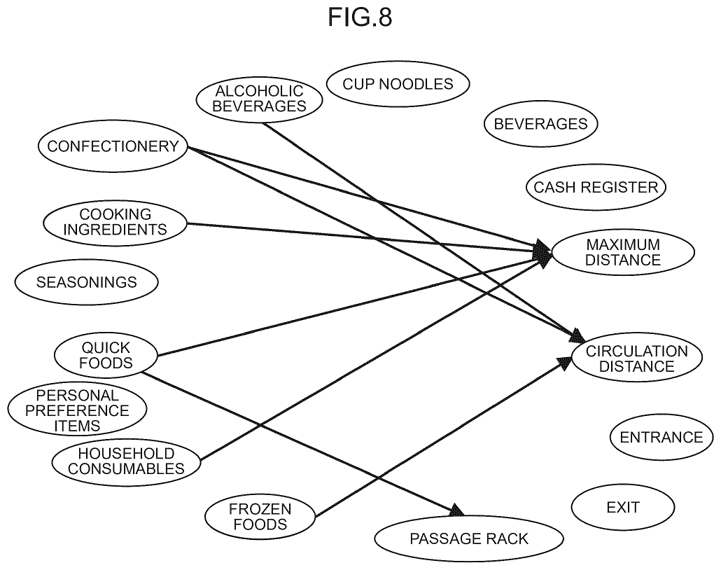

FIG. 8 illustrates an example of the first causal graph 322. The first causal graph 322 of FIG. 8 includes nodes representing frozen foods, household consumables, personal preference items, quick foods, seasonings, cooking ingredients, confectionery, alcoholic beverages, cup noodles, beverages, a cash register, a maximum distance, a circulation distance, an entrance, an exit, and a passage rack.

In the first causal search, each item in FIG. 6 is used as a variable representing each node of the first causal graph 322. In this example, K=10, and an action Aj (j=1 to 10) is used as a variable representing frozen foods, household consumables, personal preference items, quick foods, seasonings, cooking ingredients, confectionery, alcoholic beverages, cup noodles, or beverages. The arrow between the two nodes represents an edge from the node representing the cause to the node representing the result.

For example, in the causal relationship between the alcoholic beverages and the circulation distance, the alcoholic beverages represent a cause, and the circulation distance represents a result. In the causal relationship between the confectionery and the maximum distance, the confectionery represents a cause, and the maximum distance represents a result. The first causal graph 322 is an example of a causal relationship between a plurality of products and an evaluation value.

The specifying unit 313 specifies a product arrangement pattern P that affects the circulation distance or the maximum distance using the simulation result 321 and the first causal graph 322 and adds an item representing the product arrangement pattern P to the integrated behavior information.

For example, the specifying unit 313 specifies a popular product of which the customer popularity satisfies a predetermined condition among products that affect the circulation distance or the maximum distance as a popular product that affects the circulation distance or the maximum distance. Then, the specifying unit 313 specifies information on the specified arrangement of the popular products as the product arrangement pattern P. The product that affects the circulation distance or the maximum distance is, for example, a target product of the action Aj that causes the circulation distance or the maximum distance in the first causal graph 322.

In the case of the first causal graph 322 of FIG. 8, the category Cj of the target product of the action Aj that causes the circulation distance is frozen foods, confectionery, and alcoholic beverages. The category Cj of the target product of the action Aj that causes the maximum distance is household consumables, quick foods, cooking ingredients, and confectionery. Therefore, the category Cj of the product that affects the circulation distance or the maximum distance is frozen foods, household consumables, quick foods, cooking ingredients, confectionery, and alcoholic beverages.

As the popular products, for example, when the categories Cj are sorted in descending order of the action occurrence rate Rj, products belonging to the predetermined number of categories Cj from the top are used. The specifying unit 313 may use a product belonging to the category Cj having the action occurrence rate Rj larger than a predetermined threshold as the popular product.

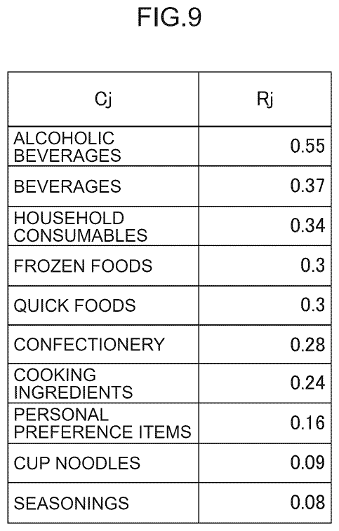

FIG. 9 illustrates an example of sorting results of the 10 categories Cj illustrated in FIG. 8. In this example, the 10 categories Cj are sorted in descending order of the action occurrence rate Rj. For example, when the top four categories Cj included in the sorting results are used as popular products, products belonging to alcoholic beverages, beverages, household consumables, and frozen foods are used as popular products.

Here, since the beverages do not affect the circulation distance or the maximum distance among the categories Cj of the popular products, the remaining alcoholic beverages, household consumables, and frozen foods are specified as the popular products that affect the circulation distance or the maximum distance.

By specifying the information on the arrangement of the popular product that affects the circulation distance or the maximum distance as the product arrangement pattern P, it is possible to perform the second causal search in which the item representing the product arrangement pattern P is added as a variable. As a result, it is possible to analyze the influence of the arrangement of the products in consideration of the preference of the customer on the circulation distance or the maximum distance from the result of the second causal search.

The specifying unit 313 may specify, as the product arrangement pattern P, information indicating that the products belonging to each of any two categories Cj among the categories Cj that affect the circulation distance or the maximum distance are arranged adjacent to each other.

By specifying information indicating that the products belonging to each of the two categories Cj are arranged adjacent to each other as the product arrangement pattern P, it is possible to perform the second causal search in which the item representing the product arrangement pattern P is added as a variable. This makes it possible to analyze the influence of the arrangement of those products on the circulation distance or the maximum distance from the result of the second causal search.

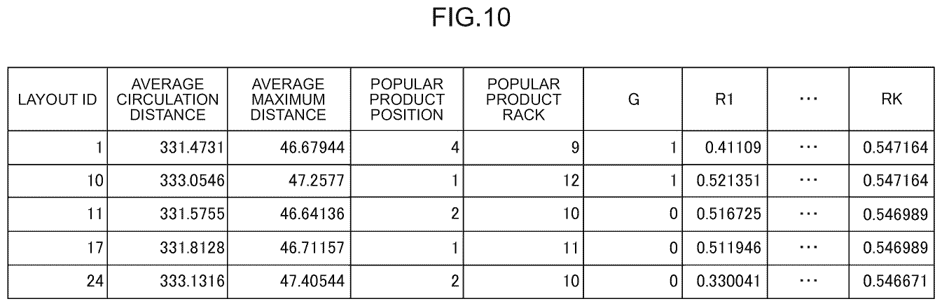

FIG. 10 illustrates an example of the integrated behavior information to which the item representing the product arrangement pattern P is added. In the integrated behavior information of FIG. 10, a popular product position, a popular product width, and a group G are added as items to the integrated behavior information of FIG. 7. The popular product position represents a start position at which the specified popular products are arranged in the product layout, and the popular product width represents a range of a product area in which the specified popular products are arranged with reference to the popular product position.

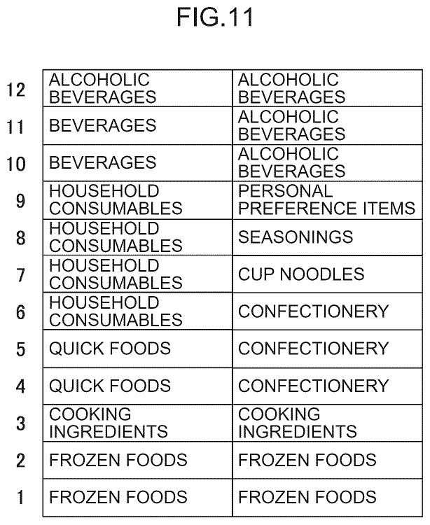

FIG. 11 illustrates an example of a product position in the product layout illustrated in FIG. 5. In this example, one number indicating the product position is assigned to two product areas arranged in a line in the left-right direction. Therefore, the product positions in the 12 columns are identified by the numbers “1” to “12”.

For example, when the category Cj of the popular product that affects the circulation distance or the maximum distance is alcoholic beverages, beverages, household consumables, and confectionery, these popular products are arranged in any of nine columns of product areas indicated by numbers “4” to “12”. In this case, among “4” to “12”, the smallest number “4” is used as the popular product position, and “9” indicating the number of columns in which the popular products are arranged is used as the popular product width.

The popular product position and the popular product width are examples of information related to arrangement of products of which the customer popularity satisfies a predetermined condition among products that affect the evaluation value.

The group G indicates whether the cooking ingredients are arranged adjacent to the frozen foods among the categories Cj that affect the circulation distance or the maximum distance in the first causal graph 322 of FIG. 8. G=1 indicates that the cooking ingredients are arranged adjacent to the frozen food, and G=0 indicates that the cooking ingredients are not arranged adjacent to the frozen food.

In the product layout of FIG. 11, G=1 because the cooking ingredients are arranged in the column “3”, and the frozen foods are arranged in the column “2” adjacent to the column “3”. The value “1” of the group G is an example of information indicating that the first product and the second product are grouped and arranged.

The specifying unit 313 records a value of the item representing the product arrangement pattern P for the product layout indicated by the layout ID in association with each layout ID of the integrated behavior information. For example, in the integrated behavior information in FIG. 10, the popular product position corresponding to the layout ID “1” is “4”, the popular product width is “9”, and thus G=1.

The specifying unit 313 may present the first causal graph 322 and the category Cj of the popular product to the user via the output unit 316. In this case, the specifying unit 313 displays, for example, the first causal graph 322 and the information indicating the category Cj of the popular product on the screen via the output unit 316.

The user determines the product arrangement pattern P with reference to the displayed first causal graph 322 and the category Cj of the popular product and inputs information indicating the determined product arrangement pattern P to the layout generation device 101. Then, the specifying unit 313 specifies the product arrangement pattern P according to the input information.

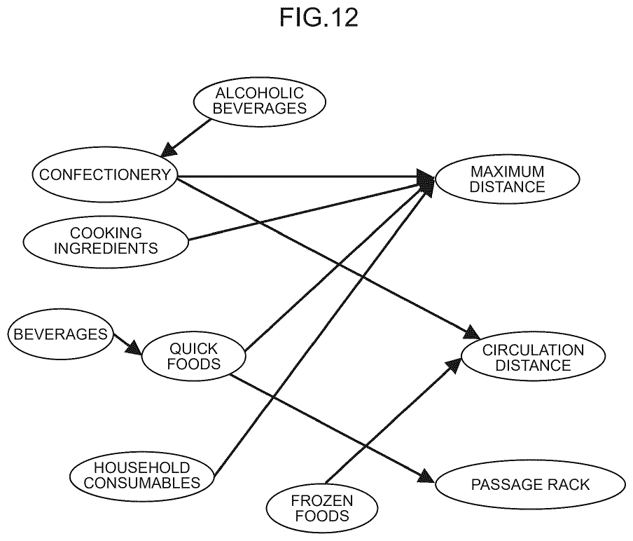

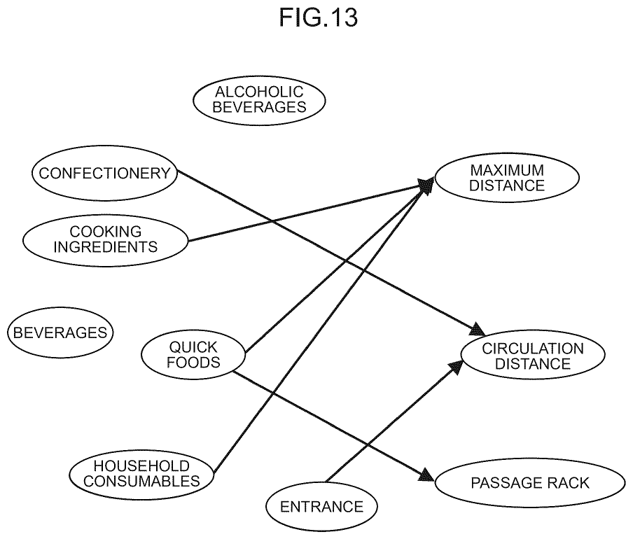

Next, another example of the product arrangement pattern P specified from the first causal graph 322 is described with reference to FIGS. 12 and 13.

FIG. 12 illustrates an example of the first causal graph 322 including a causal relationship between two products. The first causal graph 322 of FIG. 12 includes nodes representing alcoholic beverages, confectionery, cooking ingredients, beverages, quick foods, household consumables, frozen foods, the maximum distance, the circulation distance, and passage racks.

In this example, in the causal relationship between alcoholic beverages and confectionery, the alcoholic beverages represent the cause, and the confectionery represents the result. In the causal relationship between the confectionery and the maximum distance, the confectionery represents a cause, and the maximum distance represents a result. In the causal relationship between the confectionery and the circulation distance, the confectionery represents the cause, and the circulation distance represents the result. Therefore, it can be seen that the alcoholic beverages affect the maximum distance and the circulation distance via the confectionery.

Therefore, the specifying unit 313 specifies, as the product arrangement pattern P, that the alcoholic beverages are arranged adjacent to the confectionery, and adds an item G1 indicating whether the alcoholic beverages are arranged adjacent to the confectionery to the integrated behavior information. G1=1 indicates that the alcoholic beverages are arranged adjacent to the confectionery, and G1=0 indicates that the alcoholic beverages are not arranged adjacent to the confectionery. The value “1” of G1 is an example of information indicating that the first product and the second product are grouped and arranged.

In addition, in the causal relationship between the beverages and the quick foods, the beverages represent the cause, and the quick foods represent the result. In the causal relationship between the quick foods and the maximum distance, the quick foods represent the cause, and the maximum distance represents the result. Therefore, it can be seen that the beverages affect the maximum distance via the quick foods.

Therefore, the specifying unit 313 specifies, as the product arrangement pattern P, that the beverages are arranged adjacent to the quick foods, and adds an item G2 indicating whether the beverages are arranged adjacent to the quick foods to the integrated behavior information. G2=1 indicates that the beverages are arranged adjacent to the quick foods, and G2=0 indicates that the beverages are not arranged adjacent to the quick foods. The value “1” of G2 is an example of information indicating that the first product and the second product are grouped and arranged.

FIG. 13 illustrates an example of the first causal graph 322 including a causal relationship between the entrance and the circulation distance. The first causal graph 322 of FIG. 13 includes nodes representing alcoholic beverages, confectionery, cooking ingredients, beverages, quick foods, household consumables, an entrance, a maximum distance, a circulation distance, and passage racks.

In this example, in the causal relationship between the entrance and the circulation distance, the entrance represents the cause, and the circulation distance represents the result. Therefore, it can be seen that the position of the entrance where the customer enters the store affects the circulation distance. Therefore, the specifying unit 313 specifies, as the product arrangement pattern P, that the product of the specific category Cj is arranged near the specific entrance and adds an item E indicating whether the product of the specific category Cj is arranged near the specific entrance to the integrated behavior information. For example, when the specific category Cj is quick foods, and the specific entrance is an entrance “5”, E=1 indicates that the quick foods are arranged near the entrance “5”, and E=0 indicates that the quick foods are not arranged near the entrance “5”.

Similarly, the specifying unit 313 can also specify, from the first causal graph 322, that the product of the specific category Cj is arranged near the specific exit, as the product arrangement pattern P. In this case, the specifying unit 313 adds, to the integrated behavior information, an item X indicating whether the product of the specific category Cj is arranged near the specific exit.

The second causal search unit 314 performs the second causal search using the simulation result 321 to which the item representing the product arrangement pattern P has been added, generates a second causal graph 323, and stores the second causal graph in the storage unit 317. The second causal graph 323 represents a causal relationship among the categories of the products, the circulation distance and the maximum distance, and the product arrangement pattern P. The second causal graph 323 is an example of the result of the second causal search.

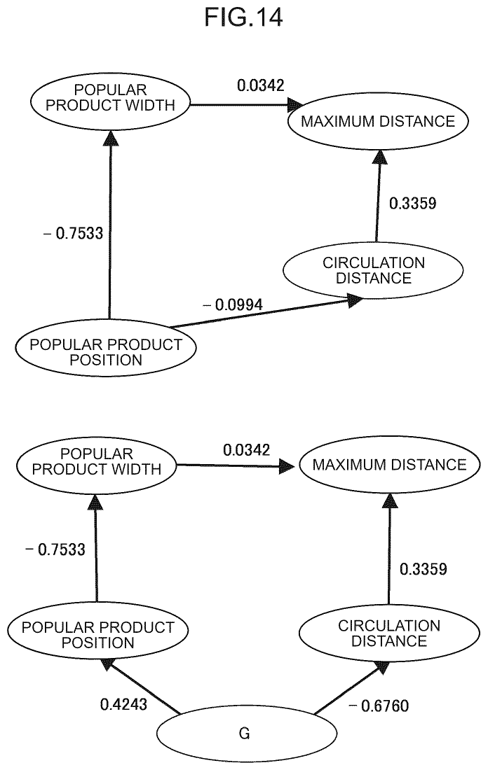

FIG. 14 illustrates an example of the causal relationship regarding the product arrangement pattern P included in the second causal graph 323. FIG. 14 includes nodes representing the maximum distance, the circulation distance, the popular product position, the popular product width, and the group G. A causal effect is applied to an edge from the node representing the cause to the node representing the result. The causal effect represents the intensity of the influence that the cause gives to the result.

In the optimization of the product layout in the store, it is desirable to generate a product layout that improves the comfort of the customer by shortening the maximum distance.

In the causal relationship between the circulation distance and the maximum distance, the circulation distance represents the cause, and the maximum distance represents the result. The causal effect of the circulation distance on the maximum distance is 0.3359. This causal relationship indicates that the greater the circulation distance, the greater the maximum distance. Therefore, in order to shorten the maximum distance and improve the comfort of the customer, it is desirable to shorten the circulation distance.

In the causal relationship between the popular product position and the circulation distance, the popular product position represents the cause, and the circulation distance represents the result. The causal effect of the popular product position on the circulation distance is-0.0994. This causal relationship indicates that as the number of the popular product positions increases, the circulation distance decreases. Therefore, in order to shorten the circulation distance and improve the comfort of the customer, it is desirable to arrange popular products in a column having a larger number.

In the causal relationship between the popular product width and the maximum distance, the popular product width represents the cause, and the maximum distance represents the result. The causal effect of the popular product width on the maximum distance is 0.0342. This causal relationship indicates that, as the popular product width increases, the maximum distance increases. Therefore, in order to shorten the maximum distance and improve the comfort of the customer, it is desirable to concentrate popular products in a narrow width area.

In the causal relationship between the popular product position and the popular product width, the popular product position represents the cause, and the popular product width represents the result. The causal effect of the popular product position on the popular product width is −0.7533. This causal relationship indicates that as the number of the popular product positions increases, the popular product width decreases. Therefore, in order to concentrate the popular products in a narrow width area and improve the comfort of the customer, it is desirable to arrange the popular products in a column with a larger number.

In the causal relationship between G and the circulation distance, G represents the cause, and the circulation distance represents the result. The causal effect of G on the circulation distance is −0.6760. This causal relationship indicates that the circulation distance decreases as G increases. If G is changed from “0” to “1”, G increases. Therefore, in order to shorten the circulation distance and improve the comfort of the customer, it is desirable to arrange the cooking ingredients adjacent to the frozen foods.

In the causal relationship between G and the popular product position, G represents the cause, and the popular product position represents the result. The causal effect of G on the popular product position is 0.4243. This causal relationship indicates that the number of the popular product positions increases as G increases. Therefore, in order to arrange the popular products in a column with a larger number and improve the comfort of the customer, it is desirable to arrange the cooking ingredients adjacent to the frozen foods.

In the second causal graph 323, the generation unit 315 checks the causal effect of each edge between the node representing the product arrangement pattern P and the node representing the maximum distance or the circulation distance. When the causal effect of each edge indicates that the maximum distance or the circulation distance is improved by adopting the product arrangement pattern P, the generation unit 315 generates an optimized product layout 324 including the product arrangement pattern P and stores the product layout in the storage unit 317. The product layout 324 is an example of a specific product layout.

For example, when the causal relationship illustrated in FIG. 14 is included in the second causal graph 323, the generation unit 315 detects that the maximum distance and the circulation distance are improved by the product arrangement pattern P of the popular product indicated by the popular product position and the popular product width. Furthermore, the generation unit 315 detects that the maximum distance and the circulation distance are improved by the product arrangement pattern P indicated by G=1.

Therefore, the generation unit 315 includes, in the product layout 324, at least one of the product arrangement pattern P of the popular product indicated by the popular product position and the popular product width and the product arrangement pattern P indicated by G=1. As a result, it is possible to generate the product layout 324 in which the maximum distance or the circulation distance is likely to be improved without relying on empirical knowledge about product sales.

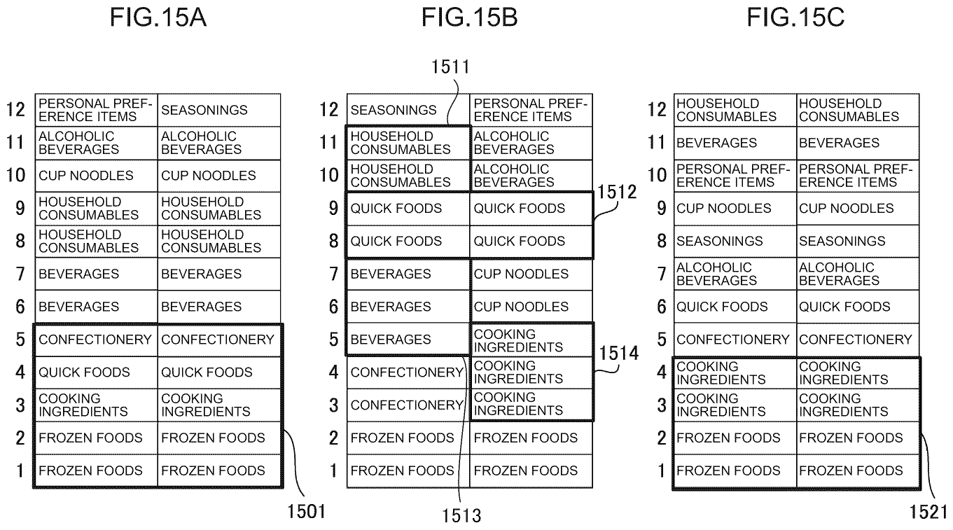

FIGS. 15A to 15C illustrate examples of the optimized product layout 324. FIG. 15A illustrates an example of a compact product layout. The product layout in FIG. 15A includes the product arrangement pattern P of the popular products, the popular product position is “1”, and the popular product width is “5”. The categories Cj of the popular products are confectionery, quick foods, cooking ingredients, and frozen foods.

First, the generation unit 315 intensively arranges confectionery, quick foods, cooking ingredients, and frozen foods in a region 1501 of the columns “1” to “5” of the product layout including the empty regions. The region 1501 is specified using the popular product position “1” and the popular product width “5”. Next, the generation unit 315 randomly arranges the remaining personal preference items, alcoholic beverages, cup noodles, household consumables, beverages, and seasonings in an empty region other than the region 1501 and generates a compact product layout.

FIG. 15B illustrates an example of a sparse product layout. The product layout in FIG. 15B includes the product arrangement pattern P of the popular products, the popular product position is “3”, and the popular product width is “9”. The categories Cj of the popular products are household consumables, quick foods, beverages, cup noodles, and cooking ingredients.

First, the generation unit 315 dispersedly arranges household consumables, quick foods, beverages, and cooking ingredients in columns “3” to “11” of the product layout including the empty regions. As a result, household consumables are arranged in a region 1511, quick foods are arranged in a region 1512, beverages are arranged in a region 1513, and cooking ingredients are arranged in a region 1514. The regions of the columns “3” to “11” are specified using the popular product position “3” and the popular product width “9”.

Next, the generation unit 315 randomly arranges the remaining seasonings, confectionery, frozen foods, personal preference items, alcoholic beverages, and cup noodles in the empty regions other than the regions 1511 to 1514 and generates the sparse product layout.

FIG. 15C illustrates an example of a product layout in which the cooking ingredients and the frozen foods are adjacent to each other. The product layout of FIG. 15C includes the product arrangement pattern P indicated by G=1.

First, the generation unit 315 arranges the cooking ingredients and the frozen foods in the region 1521 of the columns “1” to “4” of the product layout including the empty regions. As a result, the cooking ingredients are arranged adjacent to the frozen foods. Next, the generation unit 315 randomly arranges the remaining household consumables, beverages, personal preference items, cup noodles, seasonings, alcoholic beverages, quick foods, and confectionery in an empty region other than the region 1521 and generates the product layout in which the cooking ingredients and the frozen foods are adjacent to each other.

The generation unit 315 outputs the second causal graph 323 and the product layout 324 via the output unit 316. For example, the generation unit 315 displays information indicating the second causal graph 323 and the product layout 324 on the screen via the output unit 316.

As a result, the product layout 324 can be presented to the user as the optimized product layout, and the second causal graph 323 can be presented to the user as the explanatory information for explaining the optimality of the product layout 324. The second causal graph 323 illustrates the optimality of the product layout 324 from the viewpoint of the causal relationship.

For example, when the causal relationship illustrated in FIG. 14 is included in the second causal graph 323, the user can understand that the maximum distance and the circulation distance are improved by arranging the popular products in the region indicated by the popular product position and the popular product width. Further, the user may understand that arranging the cooking ingredients adjacent to the frozen food product improves maximum distance and circulation distance.

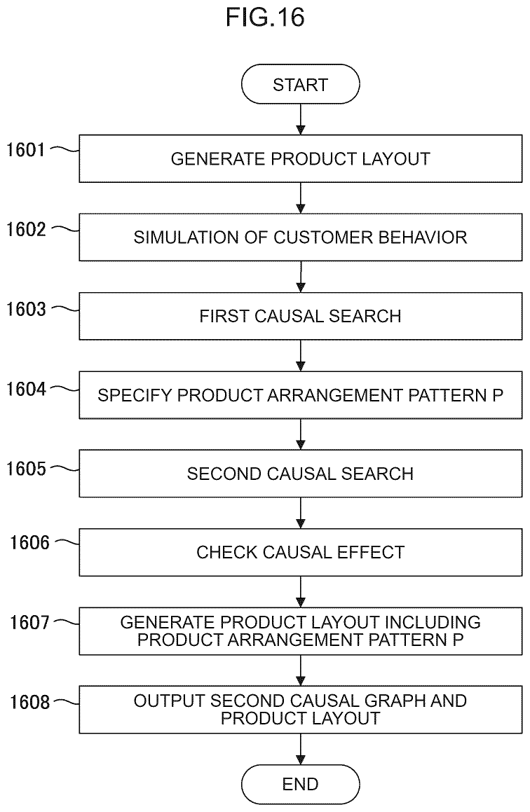

FIG. 16 is a flowchart illustrating an example of a second layout generation process performed by the layout generation device 301 in FIG. 3. First, the simulation unit 311 randomly generates N product layouts for a plurality of products to be sold in the store (step 1601). Then, the simulation unit 311 executes a simulation of a customer behavior using each product layout and generates the simulation result 321 including individual behavior information and integrated behavior information (step 1602).

Next, the first causal search unit 312 performs the first causal search using the simulation result 321 and generates the first causal graph 322 (step 1603). Then, the specifying unit 313 specifies the product arrangement pattern P using the simulation result 321 and the first causal graph 322 and adds an item representing the product arrangement pattern P to the integrated behavior information (step 1604).

Next, the second causal search unit 314 performs the second causal search using the simulation result 321 to which the item representing the product arrangement pattern P has been added and generates the second causal graph 323 (step 1605).

Next, in the second causal graph 323, the generation unit 315 checks the causal effect of each edge between the node representing the product arrangement pattern P and the node representing the maximum distance or the circulation distance (step 1606). When the causal effect of each edge indicates that the maximum distance or the circulation distance is improved by adopting the product arrangement pattern P, the generation unit 315 generates the product layout 324 including the product arrangement pattern P (step 1607).

Next, the generation unit 315 outputs the second causal graph 323 and the product layout 324 via the output unit 316 (step 1608).

The configurations of the layout generation device 101 in FIG. 1 and the layout generation device 301 in FIG. 3 are merely examples, and some components may be omitted or changed according to the application or condition of the layout generation device. For example, when a simulation of a customer behavior is executed by a device outside the layout generation device 301 in FIG. 3, the simulation unit 311 can be omitted.

The flowcharts of FIGS. 2 and 16 are merely examples, and some processes may be omitted or changed according to the configurations or conditions of the layout generation device 101 and the layout generation device 301. For example, when the simulation of the customer behavior is executed by a device outside the layout generation device 301 in FIG. 3, the processes of step 1601 and step 1602 in FIG. 16 can be omitted.

The floor map of the store illustrated in FIG. 4 is merely an example, and the floor map changes according to the store. The product layout illustrated in FIG. 5 is merely an example, and the product layout changes according to the floor map.

The simulation results 321 illustrated in FIGS. 6 and 7 are merely examples, and the simulation result 321 changes according to the product layout. The simulation result 321 may include another index other than the maximum distance and the circulation distance as the evaluation value of the product layout.

The first causal graphs 322 illustrated in FIGS. 8, 12, and 13 are merely examples, and the first causal graphs 322 change according to the simulation result 321. The sorting result of the category Cj illustrated in FIG. 9 is merely an example, and the sorting result changes according to the simulation result 321.

The integrated behavior information illustrated in FIG. 10 is merely an example, and items added to the integrated behavior information change according to the product arrangement pattern P. The product position illustrated in FIG. 11 is merely an example, and the product position changes according to the floor map.

The second causal graph 323 illustrated in FIG. 14 is merely an example, and the second causal graph 323 changes according to the simulation result 321 and the product arrangement pattern P. The product layout illustrated in each of FIGS. 15A to 15C is merely an example, and the optimized product layout changes according to the product arrangement pattern P and the second causal graph 323.

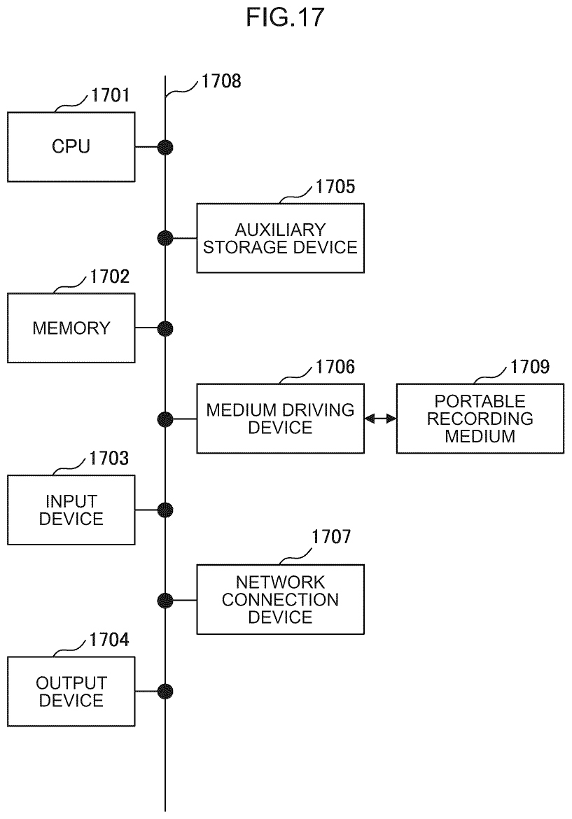

FIG. 17 illustrates a hardware configuration example of an information processing apparatus (computer) used as the layout generation device 101 in FIG. 1 and the layout generation device 301 in FIG. 3. The information processing apparatus in FIG. 17 includes a central processing unit (CPU) 1701, a memory 1702, an input device 1703, an output device 1704, an auxiliary storage device 1705, a medium driving device 1706, and a network connection device 1707. These components are hardware and are connected to each other by a bus 1708.

The memory 1702 is, for example, a semiconductor memory such as a read only memory (ROM) and a random access memory (RAM) and stores programs and data used for processing. The memory 1702 may operate as the storage unit 317 in FIG. 3.

The CPU 1701 (processor) operates as the first causal search unit 111, the specifying unit 112, the second causal search unit 113, and the generation unit 114 in FIG. 1, for example, by executing a program using the memory 1702. The CPU 1701 may also operate as the simulation unit 311, the first causal search unit 312, the specifying unit 313, the second causal search unit 314, and the generation unit 315 in FIG. 3 by executing a program using the memory 1702.

The input device 1703 is, for example, a keyboard or a pointing device and is used for inputting an instruction or information from a user or an operator. The output device 1704 is, for example, a display device, a printer, or the like and is used for an inquiry or an instruction to a user or an operator and output of a processing result. The output device 1704 may operate as the output unit 115 of FIG. 1 or the output unit 316 of FIG. 3. The processing result may be the first causal graph 322, the category Cj of the popular product, the second causal graph 323, or the product layout 324.

The auxiliary storage device 1705 is, for example, a magnetic disk device, an optical disk device, a magneto-optical disk device, or a tape device. The auxiliary storage device 1705 may be a hard disk drive or a solid state drive (SSD). The information processing apparatus can store programs and data in the auxiliary storage device 1705 and load the programs and data into the memory 1702 for use. The auxiliary storage device 1705 may operate as the storage unit 317 in FIG. 3.

The medium driving device 1706 drives a portable recording medium 1709 and accesses the recorded contents. The portable recording medium 1709 is a memory device, a flexible disk, an optical disk, a magneto-optical disk, or the like. The portable recording medium 1709 may be a compact disk read only memory (CD-ROM), a digital versatile disk (DVD), a universal serial bus (USB) memory, or the like. The user or the operator can store the program and the data in the portable recording medium 1709, load the program and the data into the memory 1702, and use the program and the data.

As described above, the computer-readable recording medium that stores the program and data used for processing is a physical (non-transitory) recording medium such as the memory 1702, the auxiliary storage device 1705, or the portable recording medium 1709.

The network connection device 1707 is a communication device that is connected to a communication network such as a wide area network (WAN) or a local area network (LAN) and performs data conversion accompanying communication. The information processing apparatus can receive the programs and data from an external device via the network connection device 1707, load the programs and data into the memory 1702, and use the programs and data. The network connection device 1707 may operate as the output unit 115 of FIG. 1 or the output unit 316 of FIG. 3.

Note that the information processing apparatus does not need to include all the components in FIG. 17, and some of the components may be omitted or changed according to the application or condition of the information processing apparatus. For example, when an interface with a user or an operator is not necessary, the input device 1703 and the output device 1704 can be omitted. When the portable recording medium 1709 or the communication network is not used, the medium driving device 1706 or the network connection device 1707 can be omitted.

According to one aspect, it is possible to present an appropriate product layout in a store.

All examples and conditional language recited herein are intended for pedagogical purposes of aiding the reader in understanding the invention and the concepts contributed by the inventors to further the art, and are not to be construed as limitations to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A non-transitory computer-readable recording medium having stored therein a layout generation program that causes a computer to execute a process comprising:
performing a first causal search for a plurality of products and an evaluation value of a product layout based on a result of a simulation of a customer behavior executed using each of a plurality of the product layouts in a store and obtaining a causal relationship between the plurality of products and the evaluation value;
specifying a product arrangement pattern that affects the evaluation value based on the causal relationship;
performing a second causal search for the plurality of products, the evaluation value, and the product arrangement pattern;
generating a specific product layout based on a result of the second causal search; and
outputting the specific product layout.

2. The non-transitory computer-readable recording medium having stored therein the layout generation program according to claim 1, wherein
the result of the simulation includes a customer popularity for each of the plurality of products, and
the specifying includes specifying, as the product arrangement pattern, information on arrangement of a product of which the customer popularity satisfies a predetermined condition among products that affect the evaluation value.

3. The non-transitory computer-readable recording medium having stored therein the layout generation program according to claim 1, wherein the specifying includes specifying, as the product arrangement pattern, information indicating that a first product and a second product are grouped and arranged among the plurality of products.

4. The non-transitory computer-readable recording medium having stored therein the layout generation program according to claim 1, wherein the evaluation value represents a movement distance of a customer or comfort of the customer in the store.

5. The non-transitory computer-readable recording medium having stored therein the layout generation program according to claim 1, wherein
the second causal search includes a causal effect of the product arrangement pattern with respect to the evaluation value, and
the generating includes,
checking the causal effect, and
causing the specific product layout to include the product arrangement pattern, when the causal effect indicates that the evaluation value is improved by the product arrangement pattern.

6. The non-transitory computer-readable recording medium having stored therein the layout generation program according to claim 5, the process further includes outputting a result of the second causal search.

7. A layout generation device comprising:
a processor configured to:
perform a first causal search for a plurality of products and an evaluation value of a product layout based on a result of a simulation of a customer behavior executed using each of a plurality of the product layouts in a store and obtain a causal relationship between the plurality of products and the evaluation value;
specify a product arrangement pattern that affects the evaluation value based on the causal relationship;
perform a second causal search for the plurality of products, the evaluation value, and the product arrangement pattern;
generate a specific product layout based on a result of the second causal search; and
output the specific product layout.

8. The layout generation device according to claim 7, wherein
the result of the simulation includes a customer popularity for each of the plurality of products, and
the processor is further configured to specify, as the product arrangement pattern, information on arrangement of a product of which the customer popularity satisfies a predetermined condition among products that affect the evaluation value.

9. The layout generation device according to claim 7, wherein the processor is further configured to specify, as the product arrangement pattern, information indicating that a first product and a second product are grouped and arranged among the plurality of products.

10. The layout generation device according to claim 7, wherein the evaluation value represents a movement distance of a customer or comfort of the customer in the store.

11. A layout generation method comprising:
performing a first causal search for a plurality of products and an evaluation value of a product layout based on a result of a simulation of a customer behavior executed using each of a plurality of the product layouts in a store and obtaining a causal relationship between the plurality of products and the evaluation value;
specifying a product arrangement pattern that affects the evaluation value based on the causal relationship;
performing a second causal search for the plurality of products, the evaluation value, and the product arrangement pattern;
generating a specific product layout based on a result of the second causal search; and
outputting the specific product layout, by a processor.

12. The layout generation method according to claim 11, wherein
the result of the simulation includes a customer popularity for each of the plurality of products, and
the specifying includes specifying, as the product arrangement pattern, information on arrangement of a product of which the customer popularity satisfies a predetermined condition among products that affect the evaluation value.

13. The layout generation method according to claim 11, wherein the specifying includes specifying, as the product arrangement pattern, information indicating that a first product and a second product are grouped and arranged among the plurality of products.

14. The layout generation method according to claim 11, wherein the evaluation value represents a movement distance of a customer or comfort of the customer in the store.
